(19) United States
(12) Patent Application Publication
(10) Pub. No.: US 2011/0089441 A1
(43) Pub. Date: Apr. 21, 2011

(54) MULTICHIP TYPE LED PACKAGE STRUCTURE FOR GENERATING LIGHT-EMITTING EFFECT SIMILAR TO CIRCLE SHAPE

(75) Inventor: Chao-Chin Wu, Taipei City (TW)

(73) Assignee: Paragon Semiconductor Lighting Technology Co., Ltd, Gueishan Township (TW)

(21) Appl. No.: 12/687,316

(22) Filed: Jan. 14, 2010

(30) Foreign Application Priority Data
Oct. 19, 2009 (TW) 98135239

(51) Int. Cl. H01L 33/00

(52) U.S. Cl. 257/91; 257/98; 257/E33.059; 257/E33.067; 257/E33.066; 257/E33.061

(57) ABSTRACT

A multichip type LED package structure for generating light-emitting effect similar to circle shape includes a substrate unit, a light-emitting unit and a package unit. The substrate unit has a substrate body and a plurality of conductive circuits separated from each other by a predetermined distance and disposed on the substrate body. Each conductive circuit has a plurality of extending portions, and the extending portions of every two conductive circuits are adjacent to each other and are alternated with each other. The light-emitting unit has a plurality of LED chips selectively electrically disposed on the substrate unit. The package unit has a light-transmitting package resin body formed on the substrate unit to cover the LED chips.

### BACKGROUND OF THE INVENTION

1. Field of the Invention

The present invention relates to a multichip type LED package structure, in particular, to a multichip type LED package structure for generating light-emitting effect similar to circle shape.

2. Description of Related Art

The invention of the lamp greatly changed the style of building construction and the living style of human beings, allowing people to work during the night. Without the invention of the lamp, we may stay in the living conditions of ancient civilizations.

Various lamps such as incandescent bulbs, fluorescent bulbs, power-saving bulbs and etc. have been intensively used for indoor illumination. These lamps commonly have the disadvantages of quick attenuation, high power consumption, high heat generation, short working life, high fragility, and being not recyclable. Further, the rapid flow of electrons (about 120 per second) through the electrodes of a regular fluorescent bulb causes an unstable current at the onset of lighting a fluorescent bulb, resulting in a flash of light that is harmful to the sight of the eyes. In order to eliminate this problem, a high frequency electronic ballast may be used. When a fluorescent or power-saving bulb is used with high frequency electronic ballast, it saves about 20% of the consumption of power and eliminates the problem of flashing. However, the high frequency electronic ballast is not detachable when installed in a fluorescent or power-saving bulb, the whole lamp assembly becomes useless if the bulb is damaged. Furthermore, because a fluorescent bulb contains a mercury coating, it may cause pollution to the environment when thrown away after damage.

Hence, LED lamp or LED tube is created in order to solve the above-mentioned questions of the prior lamp. The LED lamp or the LED tube has a plurality of LED chips and a white frame surrounding the LED chips for increasing the light-emitting efficiency of the LED chips. However, the white frame is manufactured by a predetermined mold, so that manufacturing cost is increased. In addition, when the shape of the white frame needs to be changed, the mold needs to be changed according the new shape of the white frame. In other words, the shape of the mold follows the shape of the white frame. Hence, when a new white frame is created for a new product, a new mold needs to be developed.

### SUMMARY OF THE INVENTION

In view of the aforementioned issues, the present invention provides a multichip type LED package structure for generating light-emitting effect similar to circle shape in order to steady current or voltage and increase usage lifetime.

To achieve the above-mentioned objectives, the present invention provides a multichip type LED package structure for generating light-emitting effect similar to circle shape, including: a substrate unit, a light-emitting unit and a package unit. The substrate unit has a substrate body, a first conductive circuit, a second conductive circuit and a third conductive circuit. The first conductive circuit, the second conductive circuit and the third conductive circuit are separated from each other by a predetermined distance and are disposed on the substrate body. The first conductive circuit has a first base portion and a plurality of first top extending portions extended from the first base portion; the second conductive circuit has a second base portion, a plurality of second top extending portions extended from the second base portion, a plurality of second middle extending portions extended from the second base portion and adjacent to and alternative with the first top extending portions, and at least one second bottom extending portion extended from the second base portion; the third conductive circuit has a third base portion, a plurality of third top extending portions extended from the third base portion and adjacent to and alternative with the second top extending portions, and at least one third bottom extending portion extended from the third base portion and adjacent to the at least one second bottom extending portion. The light-emitting unit has a plurality of LED chips selectively electrically disposed on the substrate unit. The package unit has a light-transmitting package resin body formed on the substrate unit to cover the LED chips.

To achieve the above-mentioned objectives, the present invention provides a multichip type LED package structure for generating light-emitting effect similar to circle shape, including: a substrate unit, a light-emitting unit and a package unit. The substrate unit has a substrate body and a plurality of conductive circuits separated from each other by a predetermined distance and disposed on the substrate body. Each conductive circuit has a plurality of extending portions, and the extending portions of every two conductive circuits are adjacent to each other and are alternated with each other. The light-emitting unit has a plurality of LED chips selectively electrically disposed on the substrate unit. The package unit has a light-transmitting package resin body formed on the substrate unit to cover the LED chips.

Therefore, the present invention at least has the following features:

1. The LED chips are divided into many LED chip sets with even LED chips, the even LED chips of each LED chip sets are electrically connected in series, and the LED chip sets are electrically connected in parallel. Of course, the LED chips also can be divided into many LED chip sets with cardinal LED chips, the cardinal LED chips of each LED chip sets are electrically connected in series, and the LED chip sets are electrically connected in parallel. Hence, the present invention has steady current or voltage and can increase usage lifetime.

2. The positive electrode and the negative electrode of each LED chip respectively correspond to at least two of the positive pads and at least two of the negative pads, so that the positive electrode of each LED chip has at least one standby positive pad and the negative electrode of each LED chip has at least one standby negative pad.

3. The present invention can form an annular reflecting resin body (an annular white resin body) with any shapes by coating method. In addition, the position of a light-transmitting package resin body such as phosphor resin can be limited in the resin position limiting space by using the annular reflecting resin body, and the shape of the light-transmitting package resin body can be adjusted by using the annular reflecting resin body. Therefore, the present invention can apply to increase light-emitting efficiency of LED chips and control light-projecting angle of LED chips.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIGS. 1A to 1D are schematic views of the multichip type LED package structure according to the first embodiment of the present invention, at different stages of the packaging processes, respectively;

FIGS. 2A to 2C are schematic views of the multichip type LED package structure according to the second embodiment of the present invention, at different stages of the packaging processes, respectively;

FIG. 3A is an exploded, schematic view of the multichip type LED package structure according to the present invention (the insulative layer, the light-reflecting unit and the package unit are removed temporarily); and

FIG. 3B is an assembled, schematic view of the multichip type LED package structure according to the present invention (the insulative layer, the light-reflecting unit and the package unit are removed temporarily).

### DETAILED DESCRIPTION OF THE PREFERRED EMBODIMENTS

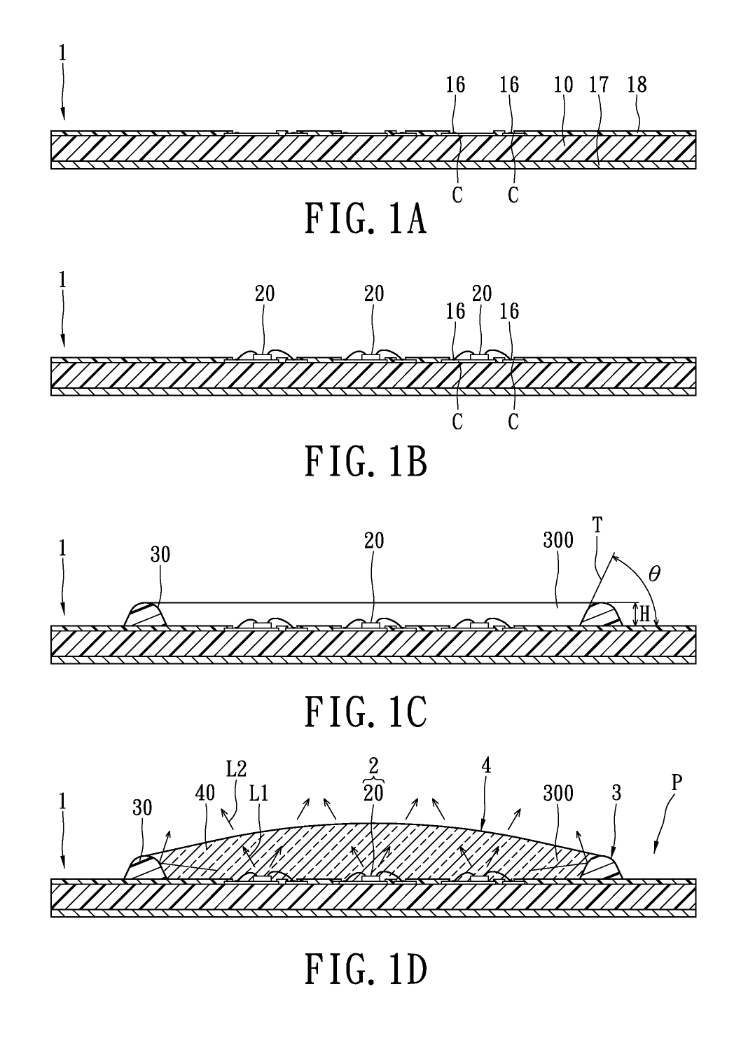

Referring to FIGS. 1A to 1D, the detail descriptions (step S100 to step S108) of the first embodiment of the present invention are shown as follows:

Referring to FIG. 1A, the method includes providing a substrate unit 1 that has a substrate body 10, a plurality of conductive circuits C disposed on the substrate body 10, a plurality of conductive pads 16 disposed on the conductive circuits C, a heat-dissipating layer 17 disposed on a bottom surface of the substrate body 10 and an insulative layer 18 disposed on a top surface of the substrate body 10 and covers one part of the conductive circuits C to expose the conductive pads 16 (step S100). Hence, the heat-dissipating efficiency of the substrate unit 1 is increased by using the heat-dissipating layer 17, and the insulative layer 18 is a solder mask for exposing the conductive pads 16 and a chip-placing area only in order to achieve local soldering. However, the above-mentioned definition of the substrate unit 1 does not limit the present invention. Any types of substrate can be applied to the present invention. For example, the substrate unit 1 can be a PCB (Printed Circuit Board), a flexible substrate, an aluminum substrate, a ceramic substrate, or a copper substrate.

Referring to FIG. 1B, the method includes selectively electrically arranging a plurality of LED chips 20 on the conductive circuits C of the substrate unit 1 (step S102). In the first embodiment, the LED chips 20 are electrically disposed between the two conductive pads 16 of every two conductive circuits C by wire bonding.

Referring to FIG. 1C, the method includes surroundingly coating liquid resin (not shown) on the top surface of the substrate unit 1 (step S104). In addition, the liquid resin can be coated on the substrate body 10 by any shapes according to different requirements (such as a circular shape, a square or a rectangular shape etc.). The thixotropic index of the liquid resin is between 4 and 6, the pressure of coating the liquid resin on the top surface of the substrate unit 1 is between 350 kpa and 450 kpa, and the velocity of coating the liquid resin on the top surface of the substrate unit 1 is between 5 mm/s and 15 mm/s. The liquid resin is surroundingly coated on the top surface of the substrate unit 1 from a start point to a termination point, and the position of the start point and the position of the termination point are the same. Furthermore, after the step S104, the method includes hardening the liquid resin to form an annular reflecting resin body 30, and the annular reflecting resin body 30 surrounding the LED chips 20 that are disposed on the substrate unit 1 to form a resin position limiting space 300 above the substrate unit 1 (step S106). In addition, the liquid resin is hardened by baking, the baking temperature is between 120° C. and 140° C., and the baking time is between 20 minute and 40 minute.

Moreover, the annular reflecting resin body 30 has an arc shape formed on a top surface thereof. The annular reflecting resin body 30 has a radius tangent T, and the angle θ of the radius tangent T relative to the top surface of the substrate unit 1 is between 40° C. and 50° C. The maximum height H of the annular reflecting resin body 30 relative to the top surface of the substrate unit 1 is between 0.3 mm and 0.7 mm, and the width of a bottom side of the annular reflecting resin body 30 is between 1.5 mm and 3 mm. The thixotropic index of the annular reflecting resin body 30 is between 4 and 6.

Referring to FIG. 1D, the method includes forming a light-transmitting package resin body 40 on the top surface of the substrate unit 1 in order to cover the LED chips 20, and the position of the light-transmitting package resin body 40 being limited in the resin position limiting space 300 (step S108). In addition, the annular reflecting resin body 30 can be a white thermohardening reflecting body (opaque resin) mixed with inorganic additive, and the top surface of the light-transmitting package resin body 40 is convex.

In the first embodiment, each LED chip 20 can be a blue LED chip, and the light-transmitting package resin body 40 can be a phosphor body. Hence, blue light beams L1 generated by the LED chips 20 (the blue LED chips) can pass through the light-transmitting package resin body 40 (the phosphor body) to generate white light beams L2 that are similar to the light source generate by sun lamp.

In other words, the light-transmitting package resin body 40 is limited in the resin position limiting space 300 by using the annular reflecting resin body 30 in order to control the usage quantity of the light-transmitting package resin body 40. In addition, the surface shape and the height of the light-transmitting package resin body 40 can be adjusted by control the usage quantity of the light-transmitting package resin body 40 in order to light-projecting angles of the white light beams L2. Moreover, the blue light beams L1 generated by the LED chips 20 can be reflected by an inner wall of the annular reflecting resin body 30 in order to increase the light-emitting efficiency of the multichip type LED package structure P of the present invention.

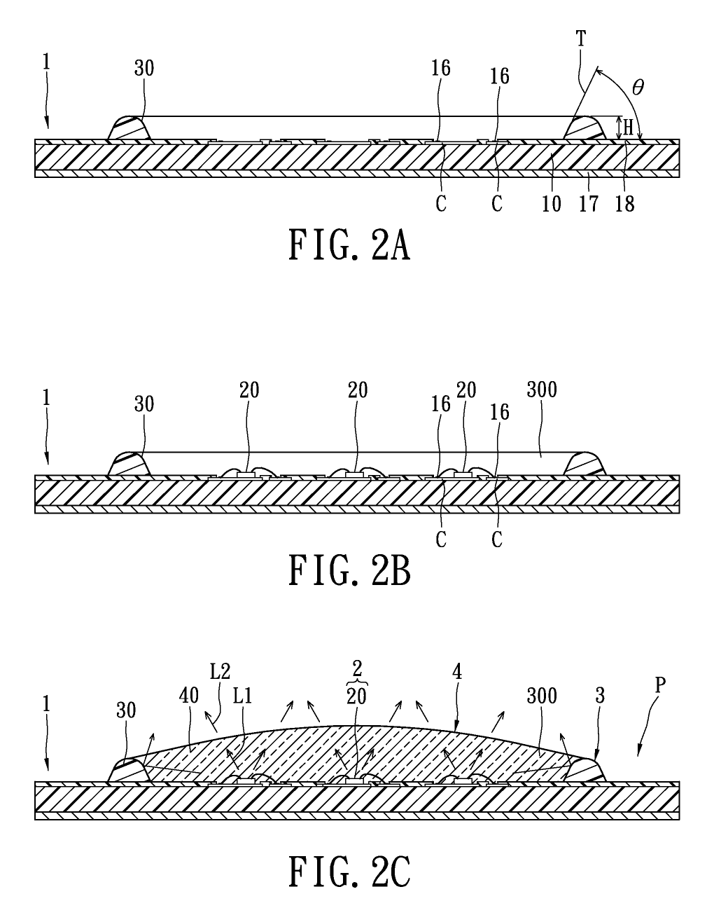

Referring to FIGS. 2A to 2C, the detail descriptions (step S200 to step S208) of the second embodiment of the present invention are shown as follows:

Referring to FIG. 2A, the method includes providing a substrate unit 1 that has a substrate body 10, a plurality of conductive circuits C disposed on the substrate body 10, a plurality of conductive pads 16 disposed on the conductive circuits C, a heat-dissipating layer 17 disposed on a bottom surface of the substrate body 10 and an insulative layer 18 disposed on a top surface of the substrate body 10 and covers one part of the conductive circuits C to expose the conductive pads 16 (step S200). Hence, the heat-dissipating efficiency of the substrate unit 1 is increased by using the heat-dissipating layer 17, and the insulative layer 18 is a solder mask for exposing the conductive pads 16 and a chip-placing area only in order to achieve local soldering. However, the above-mentioned definition of the substrate unit 1 does not limit the present invention. Any types of substrate can be applied to the present invention. For example, the substrate unit 1 can be a PCB (Printed Circuit Board), a flexible substrate, an aluminum substrate, a ceramic substrate, or a copper substrate.

Referring to FIG. 2A, the method includes surroundingly coating liquid resin (not shown) on the top surface of the substrate unit 1 (step S202). In addition, the liquid resin can be coated on the substrate body 10 by any shapes according to different requirements (such as a circular shape, a square or a rectangular shape etc.). The thixotropic index of the liquid resin is between 4 and 6, the pressure of coating the liquid resin on the top surface of the substrate unit 1 is between 350 kpa and 450 kpa, and the velocity of coating the liquid resin on the top surface of the substrate unit 1 is between 5 mm/s and 15 mm/s. The liquid resin is surroundingly coated on the top surface of the substrate unit 1 from a start point to a termination point, and the position of the start point and the position of the termination point are the same. Furthermore, after the step S202, the method includes hardening the liquid resin to form an annular reflecting resin body 30 (step S204). In addition, the liquid resin is hardened by baking, the baking temperature is between 120° C. and 140° C., and the baking time is between 20 minute and 40 minute.

Moreover, the annular reflecting resin body 30 has an arc shape formed on a top surface thereof. The annular reflecting resin body 30 has a radius tangent T, and the angle θ of the radius tangent T relative to the top surface of the substrate unit 1 is between 40° C. and 50° C. The maximum height H of the annular reflecting resin body 30 relative to the top surface of the substrate unit 1 is between 0.3 mm and 0.7 mm, and the width of a bottom side of the annular reflecting resin body 30 is between 1.5 mm and 3 mm. The thixotropic index of the annular reflecting resin body 30 is between 4 and 6.

Referring to FIG. 2B, the method includes selectively electrically arranging a plurality of LED chips 20 on the conductive circuits C of the substrate unit 1 (step S206). In the second embodiment, the LED chips 20 are electrically disposed between the two conductive pads 16 of every two conductive circuits C by wire bonding. In addition, the annular reflecting resin body 30 surrounds the LED chips 20 that are disposed on the substrate unit 1 to form a resin position limiting space 300 above the substrate unit 1.

Referring to FIG. 2C, the method includes forming a light-transmitting package resin body 40 on the top surface of the substrate unit 1 in order to cover the LED chips 20, and the position of the light-transmitting package resin body 40 being limited in the resin position limiting space 300 (step S208). In addition, the annular reflecting resin body 30 can be a white thermohardening reflecting body (opaque resin) mixed with inorganic additive, and the top surface of the light-transmitting package resin body 40 is convex.

In the second embodiment, each LED chip 20 can be a blue LED chip, and the light-transmitting package resin body 40 can be a phosphor body. Hence, blue light beams L1 generated by the LED chips 20 (the blue LED chips) can pass through the light-transmitting package resin body 40 (the phosphor body) to generate white light beams L2 that are similar to the light source generate by sun lamp.

In other words, the light-transmitting package resin body 40 is limited in the resin position limiting space 300 by using the annular reflecting resin body 30 in order to control the usage quantity of the light-transmitting package resin body 40. In addition, the surface shape and the height of the light-transmitting package resin body 40 can be adjusted by control the usage quantity of the light-transmitting package resin body 40 in order to light-projecting angles of the white light beams L2. Moreover, the blue light beams L1 generated by the LED chips 20 can be reflected by an inner wall of the annular reflecting resin body 30 in order to increase the light-emitting efficiency of the multichip type LED package structure P of the present invention.

Furthermore, referring to FIGS. 1D and 2C, the present invention provides a multichip type LED package structure P for generating light-emitting effect similar to circle shape by using the above-mentioned manufacturing method. The multichip type LED package structure P includes a substrate unit 1, a light-emitting unit 2, a light-reflecting unit 3 and a package unit 4.

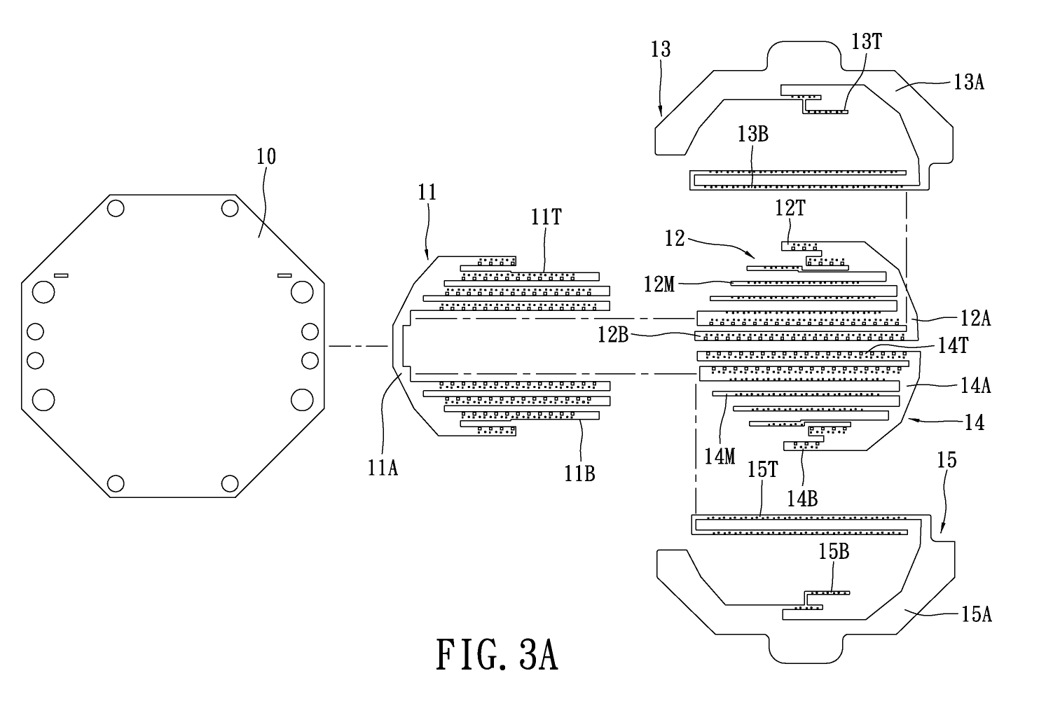

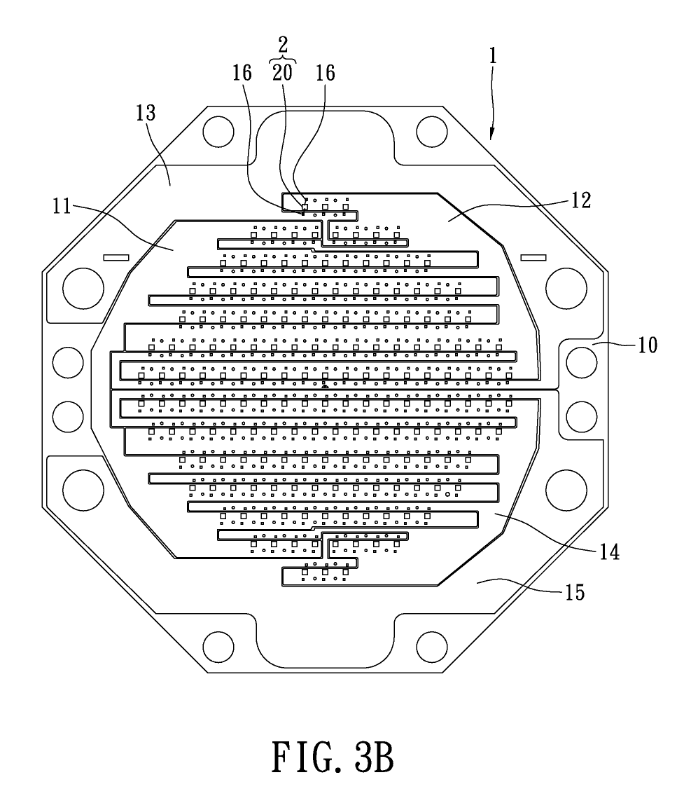

The substrate unit 1 has a substrate body 10, a first conductive circuit 11, a second conductive circuit 12, a third conductive circuit 13, a fourth conductive circuit 14 and a fifth conductive circuit 15 as shown in FIGS. 3A and 3B. The first conductive circuit 11, the second conductive circuit 12, the third conductive circuit 13, the fourth conductive circuit 14 and the fifth conductive circuit 15 are separated from each other by a predetermined distance and disposed on the substrate body 10.

Moreover, the first conductive circuit 11 has a first base portion 11A, a plurality of first top extending portions 11T extended from the first base portion 11A, and a plurality of first bottom extending portions 11B extended from the first base portion 11A.

Moreover, the second conductive circuit 12 has a second base portion 12A, a plurality of second top extending portions 12T extended from the second base portion 12A, a plurality of second middle extending portions 12M extended from the second base portion 12A and adjacent to and alternative with the first top extending portions 11T, and at least one second bottom extending portion 12B extended from the second base portion 12A. In addition, the second top extending portions 12T, the second middle extending portions 12M and the second bottom extending portion 12B are extended from the second base portion 12A along the same direction.

Besides, the third conductive circuit 13 has a third base portion 13A, a plurality of third top extending portions 13T extended from the third base portion 13A and adjacent to and alternative with the second top extending portions 12T, and at least one third bottom extending portion 13B extended from the third base portion 13A and adjacent to the at least one second bottom extending portion 12B. In addition, the third top extending portions 13T are extended from the inner side of the third base portion 13A, and the third bottom extending portion 13B is extended from one end of the third base portion 13A.

Furthermore, the fourth conductive circuit 14 has a fourth base portion 14A, at least one fourth top extending portion 14T extended from the fourth base portion 14A, a plurality of fourth middle extending portions 14M extended from the fourth base portion 14A and adjacent to and alternative with the first bottom extending portions 11B, and a plurality of fourth bottom extending portions 14B extended from the fourth base portion 14A. In addition, the fourth top extending portion 14T, the fourth middle extending portions 14M and the fourth bottom extending portions 14B are extended from the fourth base portion 14A along the same direction.

Moreover, the fifth conductive circuit 15 has a fifth base portion 15A, at least one fifth top extending portion 15T extended from the fifth base portion 15A and adjacent to the at least one fourth top extending portion 14T, and a plurality of fifth bottom extending portions 15B extended from the fifth base portion 15A and adjacent to and alternative with the fourth bottom extending portions 14B. In addition, the fifth top extending portion 15T is extended from one end of the fifth base portion 15A, and the fifth bottom extending portions 15B are extended from the inner side of the fifth base portion 15A.

Furthermore, referring to FIG. 3B, the conductive pads 16 can be selectively disposed on the first conductive circuit 11, the second conductive circuit 12, the third conductive circuit 13, the fourth conductive circuit 14 and the fifth conductive circuit 15. In other words, the substrate unit 1 has a substrate body 10 and a plurality of conductive circuits C separated from each other by a predetermined distance and disposed on the substrate body 10, and the conductive circuits C are divided into the first conductive circuit 11, the second conductive circuit 12, the third conductive circuit 13, the fourth conductive circuit 14 and the fifth conductive circuit 15. Each conductive circuit C has a plurality of extending portions, and the extending portions of every two conductive circuits C are adjacent to each other and are alternated with each other.

Besides, the light-emitting unit 2 has a plurality of LED chips 20 selectively electrically disposed on the substrate unit 1. FIG. 3B shows topmost LED chip 20 selectively electrically connected between two conductive pads 16 by wire bonding, and the LED chips 20 are arranged as a shape similar to circle. For example, the positive electrode and the negative electrode of each LED chip 20 are electrically connected to two of the conductive pads 16 via two of the conductive wires, respectively. In addition, each LED chip 20 has a positive electrode and a negative electrode, the positive electrode of each LED chip 20 corresponds to at least two of the conductive pads 16, and the negative electrode of each LED chip 20 corresponds to at least two of the conductive pads 16.

Furthermore, the LED chips 20 are arranged to form a plurality of LED chip sets parallel to each other and separated from each other by the same distance, the LED chips 20 of each LED chip sets are separated from each other by the same distance, and the LED chips 20 are alternated with each other. Referring to FIG. 3B, the LED chips 20 are divided into many LED chip sets with even LED chips 20, the even LED chips 20 of each LED chip sets are electrically connected in series, and the LED chip sets are electrically connected in parallel. For example, the LED chips 20 are divided into 44 LED chip sets with four LED chips 20, the four LED chips 20 of each LED chip sets are electrically connected in series, and the 44 LED chip sets are electrically connected in parallel. Of course, the LED chips 20 also can be divided into many LED chip sets with cardinal LED chips 20, the cardinal LED chips 20 of each LED chip sets are electrically connected in series, and the LED chip sets are electrically connected in parallel.

Moreover, the light-reflecting unit 3 has an annular reflecting resin body 30 surroundingly formed on a top surface of the substrate unit 1 by coating. The annular reflecting resin body 30 surrounds the LED chips 20 to form a resin position limiting space 300 above the substrate unit 1.

In addition, the package unit 4 has a light-transmitting package resin body 40 formed on the substrate unit 1 to cover the LED chips 20, and the position of the light-transmitting package resin body 40 is limited in the resin position limiting space 300.

Of course, the present invention can omit the usage of the light-reflecting unit 3. In other words, the light-transmitting package resin body 40 of the package unit 4 can be formed on the substrate unit 1 directly to cover the LED chips 20.

In conclusion, the present invention has the following advantages:

1. The LED chips 20 are divided into many LED chip sets with even LED chips 20, the even LED chips 20 of each LED chip sets are electrically connected in series, and the LED chip sets are electrically connected in parallel. Of course, the LED chips 20 also can be divided into many LED chip sets with cardinal LED chips 20, the cardinal LED chips 20 of each LED chip sets are electrically connected in series, and the LED chip sets are electrically connected in parallel. Hence, the present invention has steady current or voltage and can increase usage lifetime.

2. The positive electrode and the negative electrode of each LED chip respectively correspond to at least two of the positive pads and at least two of the negative pads, so that the positive electrode of each LED chip has at least one standby positive pad and the negative electrode of each LED chip has at least one standby negative pad. Hence, when a first end of the wire does not correctly connect with first one of the at least two positive pads or the at least two negative pads (it means that the wire does not electrically connect with the first one of the at least two positive pads or the at least two negative pads (such as floating solder)), the manufacturer can make the same first end of the wire connect to another one of the at least two positive pads or the at least two negative pads without cleaning solder splash on the surface of the first one of the at least two positive pads or the at least two negative pads, in order to decrease wire-bonding time (increase wire-bonding efficiency) and increase wire-bonding yield.

3. The present invention can form an annular reflecting resin body (an annular white resin body) with any shapes by coating method. In addition, the position of a light-transmitting package resin body such as phosphor resin can be limited in the resin position limiting space by using the annular reflecting resin body, and the shape of the light-transmitting package resin body can be adjusted by using the annular reflecting resin body. Therefore, the present invention can apply to increase light-emitting efficiency of LED chips and control light-projecting angle of LED chips. In other words, the light-transmitting package resin body is limited in the resin position limiting space by using the annular reflecting resin body in order to control the usage quantity of the light-transmitting package resin body. In addition, the surface shape and the height of the light-transmitting package resin body can be adjusted by control the usage quantity of the light-transmitting package resin body in order to light-projecting angles of the white light beams. Moreover, the blue light beams generated by the LED chips can be reflected by an inner wall of the annular reflecting resin body in order to increase the light-emitting efficiency of the multichip type LED package structure of the present invention.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A multichip type LED package structure for generating light-emitting effect similar to circle shape, comprising:
a substrate unit having a substrate body, a first conductive circuit, a second conductive circuit and a third conductive circuit, and the first conductive circuit, the second conductive circuit and the third conductive circuit separated from each other by a predetermined distance and disposed on the substrate body, wherein the first conductive circuit has a first base portion and a plurality of first top extending portions extended from the first base portion, the second conductive circuit has a second base portion, a plurality of second top extending portions extended from the second base portion, a plurality of second middle extending portions extended from the second base portion and adjacent to and alternative with the first top extending portions, and at least one second bottom extending portion extended from the second base portion, the third conductive circuit has a third base portion, a plurality of third top extending portions extended from the third base portion and adjacent to and alternative with the second top extending portions, and at least one third bottom extending portion extended from the third base portion and adjacent to the at least one second bottom extending portion;
a light-emitting unit having a plurality of LED chips selectively electrically disposed on the substrate unit; and
a package unit having a light-transmitting package resin body formed on the substrate unit to cover the LED chips.

2. The multichip type LED package structure according to claim 1, wherein the substrate unit has a fourth conductive circuit and a fifth conductive circuit that are separated from each other by a predetermined distance and are disposed on the substrate body; the first conductive circuit has a plurality of first bottom extending portions extended from the first base portion; the fourth conductive circuit has a fourth base portion, at least one fourth top extending portion extended from the fourth base portion, a plurality of fourth middle extending portions extended from the fourth base portion and adjacent to and alternative with the first bottom extending portions, and a plurality of fourth bottom extending portions extended from the fourth base portion; the fifth conductive circuit has a fifth base portion, at least one fifth top extending portion extended from the fifth base portion and adjacent to the at least one fourth top extending portion, and a plurality of fifth bottom extending portions extended from the fifth base portion and adjacent to and alternative with the fourth bottom extending portions.

3. The multichip type LED package structure according to claim 2, wherein the substrate unit has a plurality of conductive pads that are selectively disposed on the first conductive circuit, the second conductive circuit, the third conductive circuit, the fourth conductive circuit and the fifth conductive circuit, each LED chip has a positive electrode and a negative electrode, the positive electrode of each LED chip corresponds to at least two of the conductive pads, and the negative electrode of each LED chip corresponds to at least two of the conductive pads.

4. The multichip type LED package structure according to claim 3, wherein the substrate unit has a heat-dissipating layer disposed on a bottom surface of the substrate body and an insulative layer disposed on a top surface of the substrate body and covers one part of the conductive circuits to expose the conductive pads.

5. The multichip type LED package structure according to claim 3, further comprising a conductive wire unit that has a plurality of conductive wires, wherein the positive electrode and the negative electrode of each LED chip are electrically connected to two of the conductive pads via two of the conductive wires, respectively.

6. The multichip type LED package structure according to claim 1, wherein the LED chips are arranged as a shape similar to circle, the LED chips are arranged to form a plurality of LED chip sets parallel to each other and separated from each other by the same distance, the LED chips of each LED chip sets are separated from each other by the same distance, and the LED chips are alternated with each other.

7. The multichip type LED package structure according to claim 1, wherein the LED chips are divided into many LED chip sets with even LED chips, the even LED chips of each LED chip sets are electrically connected in series, and the LED chip sets are electrically connected in parallel.

8. The multichip type LED package structure according to claim 1, wherein the LED chips are divided into many LED chip sets with cardinal LED chips, the cardinal LED chips of each LED chip sets are electrically connected in series, and the LED chip sets are electrically connected in parallel.

9. The multichip type LED package structure according to claim 1, further comprising a light-reflecting unit that has an annular reflecting resin body surroundingly formed on a top surface of the substrate unit by coating, wherein the annular reflecting resin body surrounds the LED chips to form a resin position limiting space above the substrate unit, and the position of the light-transmitting package resin body is limited in the resin position limiting space.

10. The multichip type LED package structure according to claim 9, wherein the annular reflecting resin body has an arc shape formed on a top surface thereof, the annular reflecting resin body has a radius tangent and the angle of the radius tangent relative to the top surface of the substrate body is between 40° C. and 50° C., the maximum height of the annular reflecting resin body relative to the top surface of the substrate body is between 0.3 mm and 0.7 mm, the width of a bottom side of the annular reflecting resin body is between 1.5 mm and 3 mm, the thixotropic index of the annular reflecting resin body is between 4 and 6, and the annular reflecting resin body is a white thermohardening reflecting body mixed with inorganic additive.

11. A multichip type LED package structure for generating light-emitting effect similar to circle shape, comprising:
a substrate unit having a substrate body and a plurality of conductive circuits separated from each other by a predetermined distance and disposed on the substrate body, wherein each conductive circuit has a plurality of extending portions, and the extending portions of every two conductive circuits are adjacent to each other and are alternated with each other;
a light-emitting unit having a plurality of LED chips selectively electrically disposed on the substrate unit; and
a package unit having a light-transmitting package resin body formed on the substrate unit to cover the LED chips.

12. The multichip type LED package structure according to claim 11, wherein the conductive circuits are divided into a first conductive circuit, a second conductive circuit, a third conductive circuit, a fourth conductive circuit and a fifth conductive circuit;
wherein the first conductive circuit has a first base portion, a plurality of first top extending portions extended from the first base portion, and a plurality of first bottom extending portions extended from the first base portion;
wherein the second conductive circuit has a second base portion, a plurality of second top extending portions extended from the second base portion, a plurality of second middle extending portions extended from the second base portion and adjacent to and alternative with the first top extending portions, and at least one second bottom extending portion extended from the second base portion;
wherein the third conductive circuit has a third base portion, a plurality of third top extending portions extended from the third base portion and adjacent to and alternative with the second top extending portions, and at least one third bottom extending portion extended from the third base portion and adjacent to the at least one second bottom extending portion;
wherein the fourth conductive circuit has a fourth base portion, at least one fourth top extending portion extended from the fourth base portion, a plurality of fourth middle extending portions extended from the fourth base portion and adjacent to and alternative with the first bottom extending portions, and a plurality of fourth bottom extending portions extended from the fourth base portion;
wherein the fifth conductive circuit has a fifth base portion, at least one fifth top extending portion extended from the fifth base portion and adjacent to the at least one fourth top extending portion, and a plurality of fifth bottom extending portions extended from the fifth base portion and adjacent to and alternative with the fourth bottom extending portions.

13. The multichip type LED package structure according to claim 12, wherein the substrate unit has a plurality of conductive pads that are selectively disposed on the first conductive circuit, the second conductive circuit, the third conductive circuit, the fourth conductive circuit and the fifth conductive circuit, each LED chip has a positive electrode and a negative electrode, the positive electrode of each LED chip corresponds to at least two of the conductive pads, and the negative electrode of each LED chip corresponds to at least two of the conductive pads.

14. The multichip type LED package structure according to claim 13, wherein the substrate unit has a heat-dissipating layer disposed on a bottom surface of the substrate body and an insulative layer disposed on a top surface of the substrate body and covers one part of the conductive circuits to expose the conductive pads.

15. The multichip type LED package structure according to claim 13, further comprising a conductive wire unit that has a plurality of conductive wires, wherein the positive electrode and the negative electrode of each LED chip are electrically connected to two of the conductive pads via two of the conductive wires, respectively.

16. The multichip type LED package structure according to claim 11, wherein the LED chips are arranged as a shape similar to circle, the LED chips are arranged to form a plurality of LED chip sets parallel to each other and separated from each other by the same distance, the LED chips of each LED chip sets are separated from each other by the same distance, and the LED chips are alternated with each other.

17. The multichip type LED package structure according to claim 11, wherein the LED chips are divided into many LED chip sets with even LED chips, the even LED chips of each LED chip sets are electrically connected in series, and the LED chip sets are electrically connected in parallel.

18. The multichip type LED package structure according to claim 11, wherein the LED chips are divided into many LED chip sets with cardinal LED chips, the cardinal LED chips of each LED chip sets are electrically connected in series, and the LED chip sets are electrically connected in parallel.

19. The multichip type LED package structure according to claim 11, further comprising a light-reflecting unit that has an annular reflecting resin body surroundingly formed on a top surface of the substrate unit by coating, wherein the annular reflecting resin body surrounds the LED chips to form a resin position limiting space above the substrate unit, and the position of the light-transmitting package resin body is limited in the resin position limiting space.

20. The multichip type LED package structure according to claim 19, wherein the annular reflecting resin body has an arc shape formed on a top surface thereof, the annular reflecting resin body has a radius tangent and the angle of the radius tangent relative to the top surface of the substrate body is between 40° C. and 50° C., the maximum height of the annular reflecting resin body relative to the top surface of the substrate body is between 0.3 mm and 0.7 mm, the width of a bottom side of the annular reflecting resin body is between 1.5 mm and 3 mm, the thixotropic index of the annular reflecting resin body is between 4 and 6, and the annular reflecting resin body is a white thermohardening reflecting body mixed with inorganic additive.
